(19) United States
(12) Patent Application Publication
(10) Pub. No.: US 2014/0145647 A1
(43) Pub. Date: May 29, 2014

(54) Optical Tilted Charge Devices And Techniques

(71) Applicant: Quantum Electro Opto Systems Sdn. Bhd., Melaka (MY)

(72) Inventor: Gabriel Walter, Madison, WI (US)

(73) Assignee: Quantum Electro Opto Systems Sdn. Bhd., Melaka (MY)

(21) Appl. No.: 14/088,778

(22) Filed: Nov. 25, 2013

Related U.S. Application Data
(60) Provisional application No. 61/796,965, filed on Nov. 26, 2012.

(51) Int. Cl. H01L 33/06; H01L 33/32; H01L 33/00

(52) U.S. Cl. CPC H01L 33/06; H01L 33/0025; H01L 33/32
USPC 315/313; 257/13; 315/362

(57) ABSTRACT

A method for producing light emission, including the following steps: providing a layered semiconductor structure that includes a collector region, a first base region, a first emitter region, a coupling region, a second base region, and a second emitter region; providing a quantum size region within the second base region; and applying electrical signals with respect to the second emitter region, the first base region and the collector region, to produce light emission from the second base region.

### PRIORITY CLAIM

Priority is claimed from U.S. Provisional Patent Application No. 61/796,965, filed Nov. 26, 2012, and said Provisional patent application is incorporated herein by reference.

### FIELD OF THE INVENTION

This invention relates to the field of semiconductor light emitting devices and techniques and, more particularly, to tilted charge light emitting devices and methods, including such devices and methods that have improved efficiency and manufacturability.

### BACKGROUND OF THE INVENTION

Included in the background of the present invention are technologies relating to heterojunction bipolar transistors (HBTs, which are electrical tilted charge devices) and light-emitting transistors, transistor lasers, and tilted charge light-emitting diodes (respectively, LETs, TLs, and TCLEDs, all of which are optical tilted charge devices). A tilted charge device gets its name from the energy diagram characteristic in the device's base region, which has, approximately, a descending ramp shape from the emitter interface to the collector (or drain, for a two terminal device) interface. This represents a tilted charge population of carriers that are in dynamic flow—“fast” carriers recombine, and “slow” carriers exit via the collector (or drain).

Regarding optical tilted charge devices and techniques, which typically employ one or more quantum size regions in the device's base region, reference can be made, for example, to U.S. Pat. Nos. 7,091,082, 7,286,583, 7,354,780, 7,535,034, 7,693,195, 7,696,536, 7,711,015, 7,813,396, 7,888,199, 7,888,625, 7,953,133, 7,998,807, 8,005,124, 8,179,937, 8,179,939, 8,494,375, and 8,509,274; U.S. Patent Application Publication Numbers US2005/0040432, US2005/0054172, US2008/0240173, US2009/0134939, US2010/0034228, US2010/0202483, US2010/0202484, US2010/0272140, US2010/0289427, US2011/0150487, and US2012/0068151; and to PCT International Patent Publication Numbers WO/2005/020287 and WO/2006/093883 as well as to the publications referenced in U.S. Patent Application Publication Number US2012/0068151.

An optical tilted charge device includes an active region with built-in free majority carriers of one polarity. At one input to this active region, a single species of minority carriers of opposite polarity are injected and allowed to diffuse across the active region. This active region has features that enable and enhance the conduction of majority carriers and the radiative recombination of minority carriers. On the output side of the region, minority carriers are then collected, drained, depleted or recombined by a separate and faster mechanism. Electrical contacts are coupled to this full-featured region.

An optical tilted charge diode, in certain applications, enables more uniform current distribution. However, due to the diode configuration of the device, its electrical input impedance is generally too low for efficient driving; that is, much less than the typically required 50 ohms.

A quantum well optical tilted charge transistor (e.g. a light-emitting transistor), offers two port capabilities which a diode tilted charge device lacks. An optical tilted charge transistor can therefore be biased at relatively higher input impedance (e.g. base input in a common emitter configuration) leading to a device that is easier to operate. However, the incorporation of the quantum well structure in the base of an optical tilted charge transistor results in low electrical gain (lc/lb), lower electrical speed (ft) and more serious emitter crowding related issues. The lower gain and lower ft limits the usability of its electrical output port.

It is among the objects of the present invention to address these and other limitations of prior art approaches regarding tilted charge light-emitting devices. It is also among the objectives hereof to devise improved light-emitting semiconductor devices and techniques.

### SUMMARY OF THE INVENTION

In accordance with an embodiment of a first form of the invention, a method is set forth for producing light emission, comprising the following steps: providing a layered semiconductor structure that includes a collector region, a first base region, a first emitter region, a coupling region, a second base region, and a second emitter region; providing a quantum size region within said second base region; and applying electrical signals with respect to said second emitter region, said first base region and said collector region, to produce light emission from said second base region. In a disclosed embodiment of this form of the invention, the step of providing a coupling region comprises providing an electrical drain/coupler selected from the group consisting of a zener diode, a backward diode, a resonant tunneling diode, and an esaki diode. In another disclosed embodiment of this form of the invention, the step of providing said layered semiconductor structure comprises depositing arsenic based III-V semiconductor materials for said collector region, said first base region, said first emitter region, said coupling region, said second base region, and said second emitter region. Alternatively, lattice matched wide band gap phosphide based layers can be used for at least one of said first or second emitter regions. In another embodiment of this form of the invention, there is further provided a quantum size region in said first base region such that said collector region, said first base region, and said first emitter region operates as a further light-emitter in response to said application of electrical signals with respect to said second emitter region, said first base region, and said collector region.

In accordance with an embodiment of another form of the invention, a method is set forth for producing light emission, comprising the following steps: providing a layered heterojunction bipolar transistor structure that includes a collector region, a first base region disposed on said collector region, and a first emitter region disposed on said first base region; disposing, over the first emitter region of said transistor structure, in stacked arrangement, a plurality of (or several) layered semiconductor tilted charge light-emitting units, each unit comprising, bottom to top, a coupling region, a second base region containing a quantum size region, and a second emitter region; and applying electrical signals with respect to the second emitter region of the top unit of the stack, said first base region, and said collector region to produce light emission from the second base region of each of said units. In a disclosed embodiment of this form of the invention, the step of providing said coupling regions of said units comprises providing an electrical drain/coupler for each of said units selected from the group consisting of a zener diode, a backward diode, a resonant tunneling diode, and an esaki diode. Also in an embodiment of this form of the invention, the step of providing said layered semiconductor structure comprises depositing arsenic based III-V semiconductor materials for said collector region, said first base region, said first emitter region, each of said coupling regions, each of said second base regions, and each of said second emitter regions. Again, lattice matched wide band gap phosphide based layers can be used for at least one of said first or second emitter regions.

In accordance with an embodiment of a further form of the invention, a method is set forth for producing light emission, comprising the following steps: providing a semiconductor substrate; disposing, on said substrate, in stacked arrangement, a plurality of (or a multiplicity of) layered semiconductor tilted charge light-emitting units, each unit comprising, bottom to top, a coupling region, a base region containing a quantum size region, and an emitter region; and applying electrical signals with respect to the emitter region of the top unit of the stack and the coupling region of the bottom unit of the stack to produce light emission from the base region of each of said units. In a disclosed embodiment of this form of the invention, each of said emitter regions are provided as semiconductor material of a first conductivity type, and each of said base regions are provided as semiconductor material of a second conductivity type. Also, the coupling region of each unit is provided as a drain/coupler selected from the group consisting of a zener diode, a backward diode, a resonant tunneling diode, and an esaki diode.

Further features and advantages of the invention will become more readily apparent from the following detailed description when taken in conjunction with the accompanying drawings.

### BRIEF DESCRIPTION OF THE DRAWINGS

FIG. 1 is a simplified cross-sectional diagram of a device in accordance with an embodiment of the invention and which can be used in practicing an embodiment of a method in accordance with the invention.

FIG. 2 is a table showing an example of a more detailed layer structure of the FIG. 1 embodiment.

FIG. 3 is a table showing another example of a layer structure for the FIG. 1 embodiment, using all arsenide materials.

FIG. 4 is a simplified cross-sectional diagram of a device in accordance with another embodiment of the invention and which can be used in practicing another embodiment of a method in accordance with the invention.

FIG. 5 is a table showing an example of a more detailed layer structure of the FIG. 4 embodiment.

FIG. 6 is a simplified cross-sectional diagram of a device in accordance with a further embodiment of the invention and which can be used in practicing a further embodiment of a method in accordance with the invention.

FIG. 7 is a table showing an example of a more detailed layer structure of the FIG. 6 embodiment.

FIG. 8 is a simplified cross-sectional diagram of a device in accordance with a still further embodiment of the invention and which can be used in practicing a still further embodiment of a method in accordance with the invention.

FIG. 9 is a table showing an example of a more detailed layer structure of the FIG. 8 embodiment.

### DETAILED DESCRIPTION

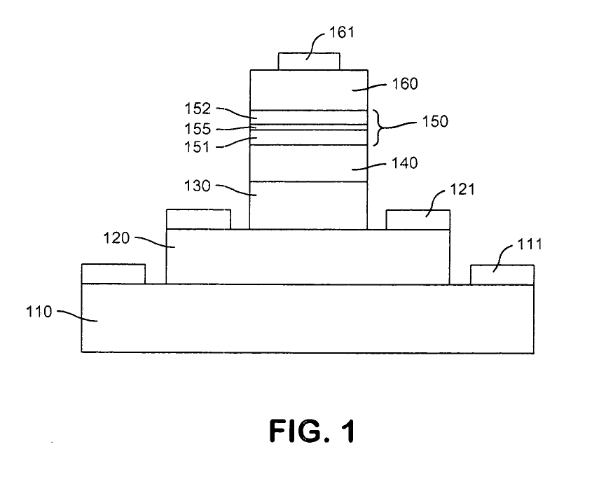

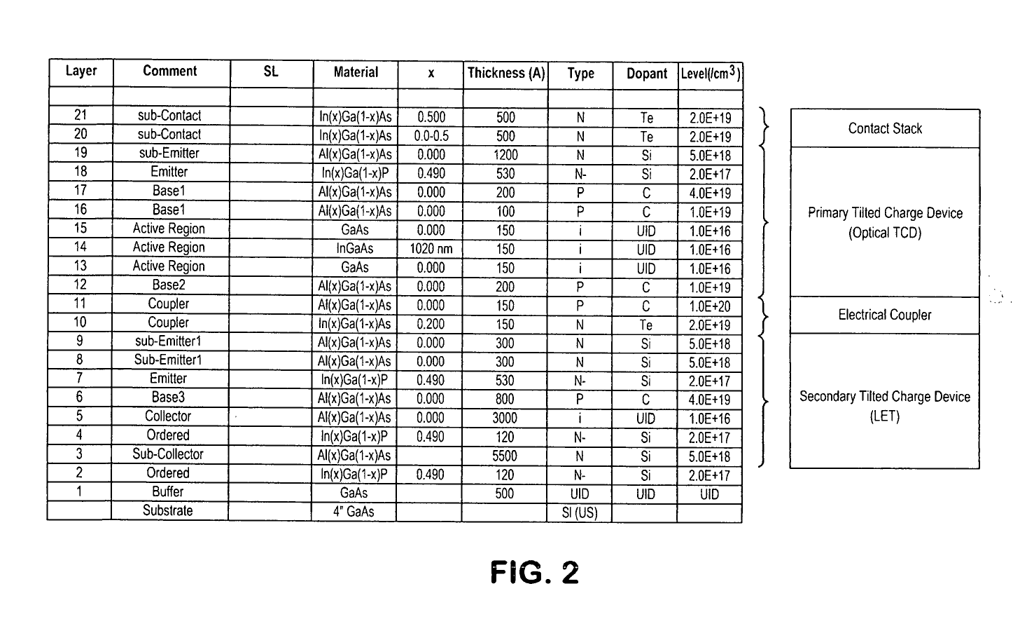

Referring to FIG. 1, there is shown a simplified cross-section of a device in accordance with an embodiment of the invention, and which can be used in practicing an embodiment of a method in accordance with the invention. The semiconductor layer structure of an example of this embodiment is shown in the table of FIG. 2. A collector region 110 has a base region 120 disposed as a mesa thereon, and an emitter region 130 is disposed as a mesa on the base region 120. A collector terminal 111 and a base terminal 121 are respectively coupled with the collector 110 and the base 120. The described collector 110, base 120, and emitter 130 of the present example are set forth in further detail in the layer table of FIG. 2, which lists a GaAs substrate and a GaAs buffer layer (1) on which the described collector 110, base 120, and emitter 130 are deposited, with the listed intervening layers and auxiliary layers. The resultant device operates as a heterojunction bipolar transistor (HBT), which is an electrical tilted charge device, referred to in the righthand box of FIG. 2 as a secondary tilted charge device. Deposited on the secondary tilted charge device is an electrical coupler 140 comprising a highly doped pn junction (layers 11 and 10 in FIG. 2) which, as previously described can be, for example, a zener diode, a backward diode, a resonant tunneling diode, or an esaki diode. Next, in FIG. 1, is disposed a base region 150, an emitter region 160, and an emitter terminal 161. The base region 150 includes at least one quantum size region 155. As used herein, a quantum size region may comprise, for example, a quantum well, quantum dots, and/or quantum wires. In the examples hereof, quantum wells are set forth. Also, as used herein, a base region can be asymmetrical, which has certain advantages as described, for example, in U.S. Patent Application Publication No. US2010/0202484. As disclosed therein, the base region can comprise base sub-regions, having band structures that are asymmetrical with respect to each other, such as the base sub-regions 151 and 152 of FIG. 1. (In the table of FIG. 2, see the layers 12-17, including the quantum well (layer 14), with adjacent base sub-region layers.)

As referenced in the box at the righthand side of FIG. 2, the upper coupled device comprises a substantial operative portion of an optical tilted charge device which produces light emission from its relatively highly doped base region containing a quantum well to enhance radiative communication. (As used herein, relatively heavily doped means carriers numbering at least about 10¹⁸ cm⁻³ for p-type and 10¹⁷ cm⁻³ for n-type). The heterojunction bipolar transistor structure beneath the electrical coupler serves as an effective controlled “drain” or “collector” for the upper tilted charge light-emitting portion of the disclosed stacked semiconductor structure. In this embodiment, and others hereof, light emission can be designed for vertical or lateral emission, with vertical emission presently preferred, through the bottom or top of the stacked arrangement. If desired, a collimator or focusing lens (not shown) can be molded to or affixed to the GaAs substrate. The collimator or lens can be advantageously formed of silicon. When the device is grown on a GaAs-on-Si substrate, the lens can be formed by etching the silicon. This embodiment, and others hereof, can also be operated as a laser by providing a suitable resonant optical cavity. Reference can be made to U.S. Patent Application Publication Numbers US2010/0202483, US2012/0068151, US2013/0126825, and 2013/0126826.

In the example of FIG. 2 contact metalization is deposited on layer 21 (for emitter terminal 161), on layer 6 (for base terminal 121), and on layer 3 (for collector terminal 111). In an example of operation, V_{BE}>2.6 volts for forward biased turn on mode, and −5 volts<V_{BC}<0.8 volts for high impedance mode. In the example of FIG. 2, the Zener diode functions as an electrical coupler and an internal voltage step-down device.

The vertically stacked and coupled tilted charge devices, as in the embodiment of FIGS. 1 and 2, combines the more uniform current distribution of the optical tilted charge diode and a high gain ((β>40) electrical tilted charge transistor. The optical tilted charge diode current output is electrically coupled to the emitter of the high speed electrical tilted charge transistor. Viewed another way, the electrical tilted charge transistor effectively functions as the drain for the tilted charge light-emitting diode.

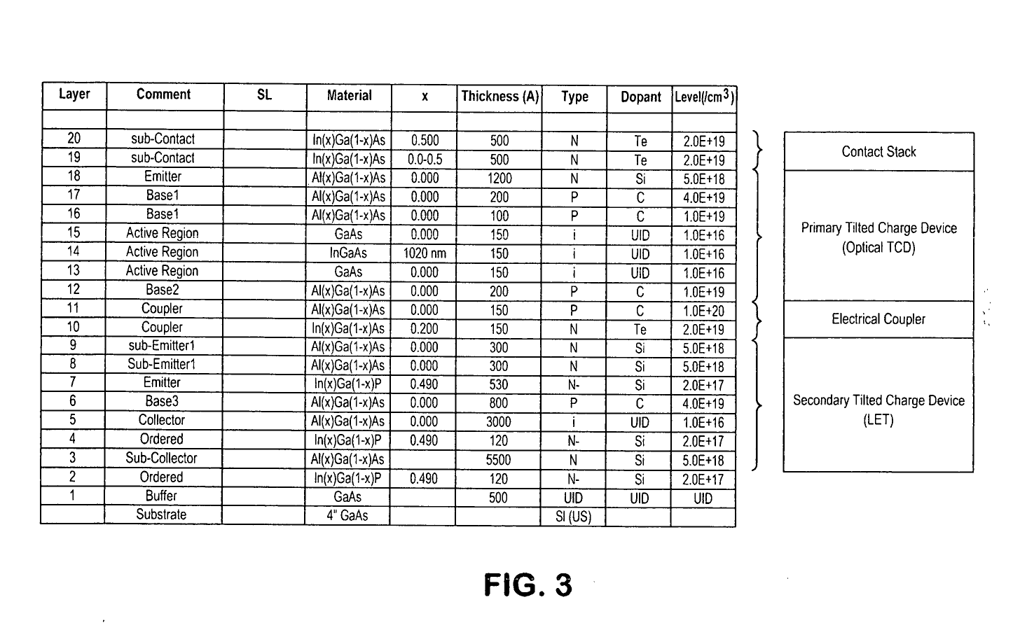

An advantage of an optical tilted charge transistor structure is the ease of fabrication due to compatibility with existing heterojunction bipolar transistor (HBT) foundry processes. The relatively thin structure (less than about 3000 Angstroms) of the tilted charge light-emitting diode, which could be fabricated substantially entirely in Arsenic based semiconductor (e.g. GaAs, InGaAs, AlGaAs), as in the FIG. 3 example, maintains process compatibility and therefore allows the tilted charge diode mesa (and active area) to be defined in the same process which defines the emitter mesa of the electrical tilted charge transistor. A vertically stacked structure eliminates the need for a wide bandgap emitter (which also functions to reduce hole flow from the p-type base material to the n-type emitter) in both tilted charge devices. In these and other embodiments, oxide collars may also be introduced in sub-emitter layers to aid in current confinement and optical extraction.

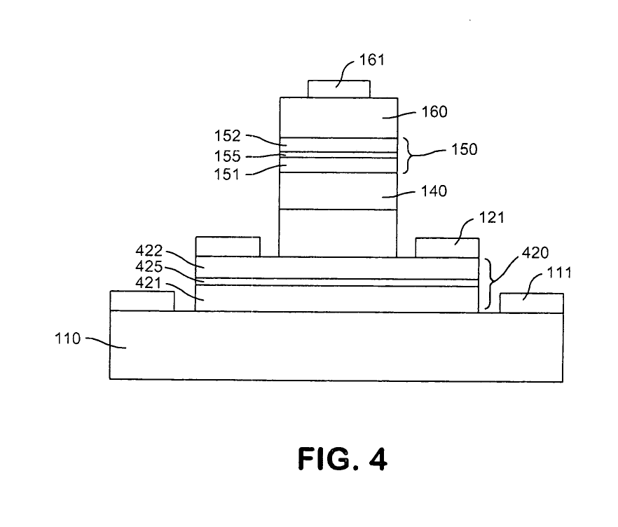

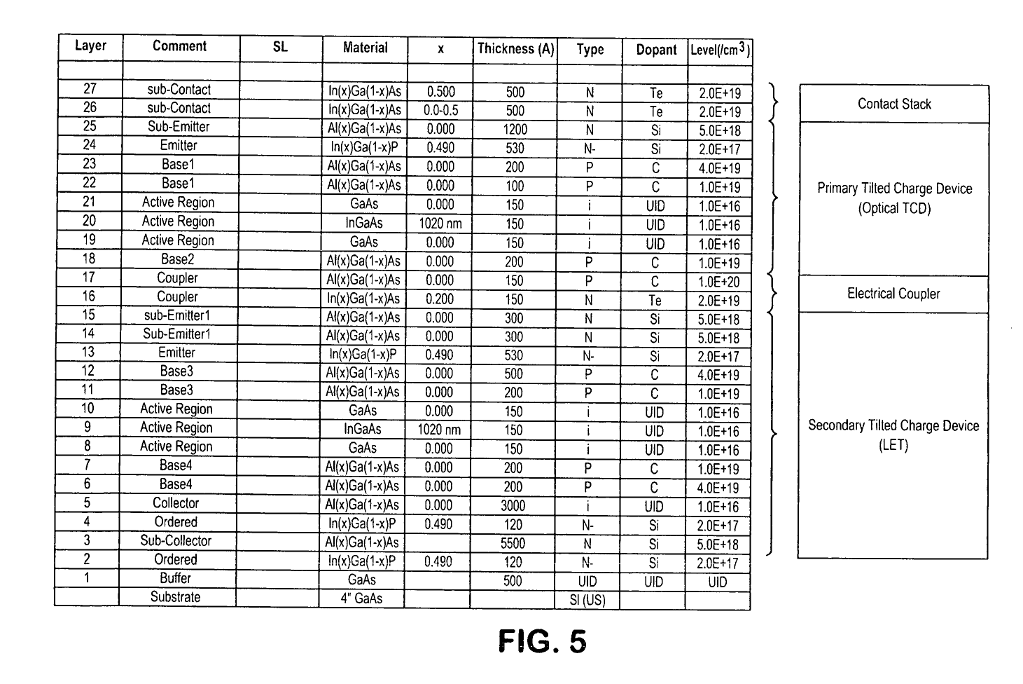

In the embodiment of FIGS. 4 and 5 the secondary tilted charge transistor device of FIG. 1 (which was an HBT in that embodiment) also functions as a light emitter; that is, a light-emitting transistor (LET). The simplified diagram of FIG. 4 has elements that correspond to those of FIG. 1 where like reference numerals are utilized, including collector 110, emitter 130, coupler 140, base 150 and quantum size region 155 of the optical tilted charge device, and emitter 160, as well as collector, base, and emitter terminals 111, 121 and 161, respectively. However, the FIG. 4 embodiment has a base region 420 with quantum size region 425 and base sub-regions 421 and 422. In the more detailed layer structure diagram of FIG. 5, reference can be made to layers 6-12 which comprise the base region (420 in FIG. 4), including the quantum well (layer 9) as part of the active region (layers 8, 9, and 10) of the base region where most of the optical emission occurs.

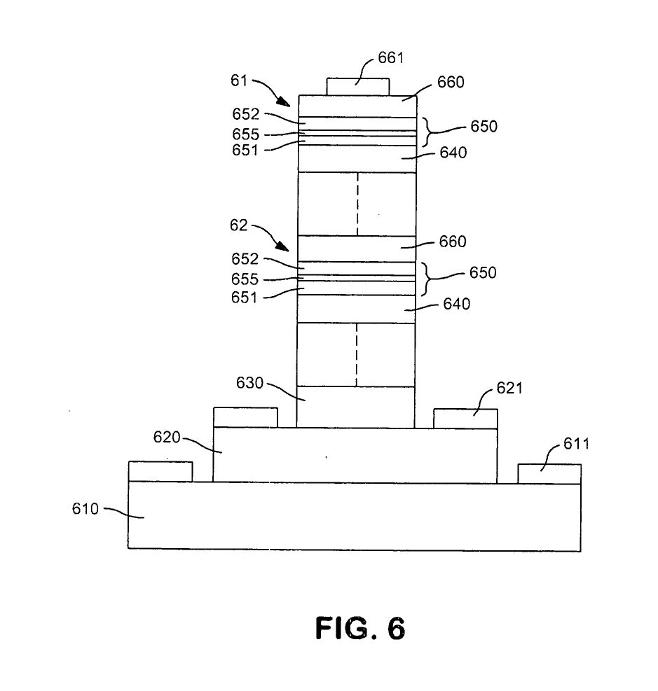

As previously noted, an important factor in the development of a spontaneous emission tilted charge device is the need to reduce the overall dimension of the device, in order to approximate a point source. An approximate point source, when coupled to a lens extraction structure, provides optimum extraction and coupling efficiency. However, the reduction in size limits the active region. The embodiments of FIGS. 6-9 address and solve this and other limitations of prior art approaches.

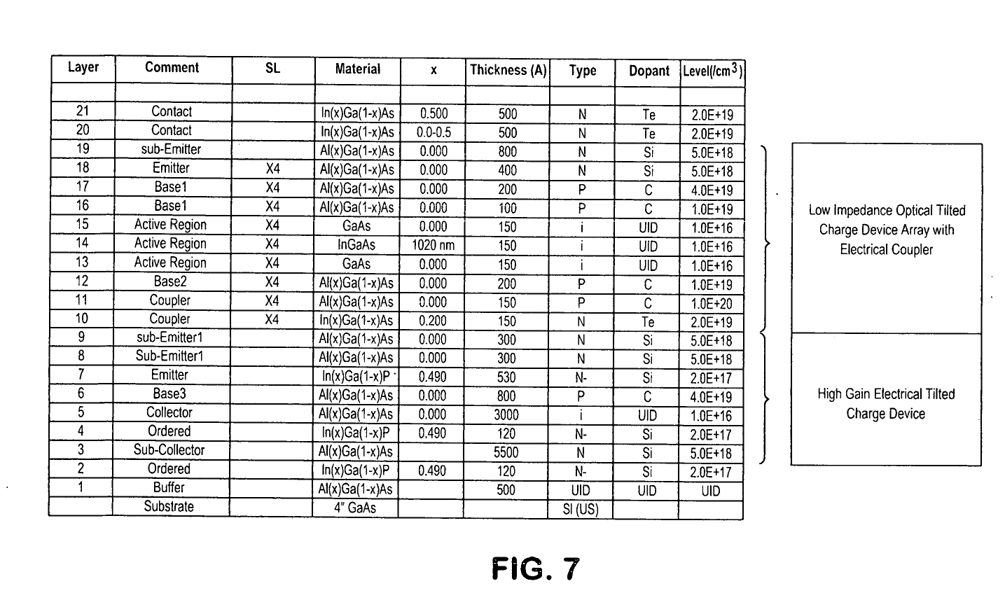

Referring to FIG. 6, there is shown a simplified cross-section of a device in accordance with another embodiment of the invention and which can be used in practicing another embodiment of a method in accordance with the invention. The semiconductor layer structure of an example of this embodiment is shown in FIG. 7. The bottom portion of the device of this embodiment is a relatively high gain electrical tilted charge device; i.e., an HBT that includes (referencing FIG. 6) collector region 610, base region 620 emitter region 630, collector terminal 611, and base terminal 621.

In the upper portion of FIG. 6, there are shown two representative light-emitting units 61 and 62, of which a plurality, and preferably several, such units are in a stack. Each such unit comprises, from bottom to top, a coupling region 640, a base region 650 containing a quantum size region 655 and comprising base sub-regions 651 and 652, and an emitter region 660. The emitter region of the top unit (61) of the stack has an emitter terminal 661. In the example of the FIG. 7 layer structure table, the layers of individual light-emitting units (e.g. unit 62 of FIG. 6) are set forth as layers 10-18. The “X4” designation in the “SL” (superlattice) column of the table means that there are four repetitions (four light-emitting units) in the stack of this example. It will be understood that this number can be varied for a desired application.

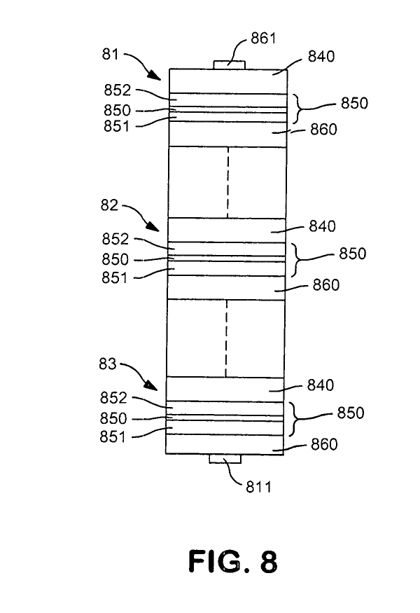

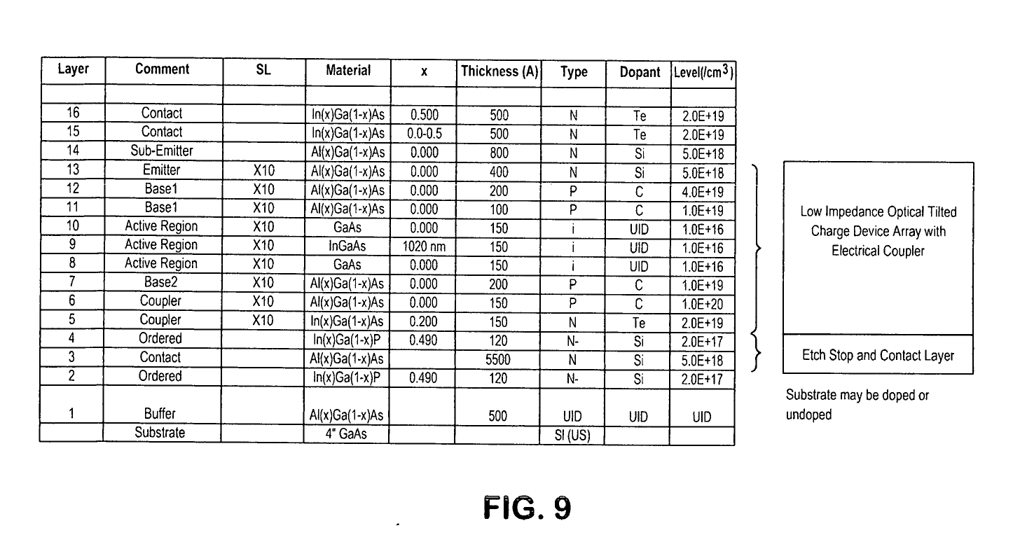

Another advantage of the stacked structures (of FIGS. 6, 7, and also FIGS. 8, 9 to be described) are the required higher operating DC voltages, which are better matched to most standard supply voltages (e.g. 3.3 V and 5 V), and therefore eliminate the need to step-down the supply voltages, which can involve additional components and wasted energy. Furthermore, a vertical stacked structure, despite the increasing number of quantum structures for optical recombination, does not effectively increase the capacitance of the device (relative to a single optical tilted charge device), but rather reduces the capacitance. For example, if each tilted charge device has a capacitance of 50 pF, two vertically stacked tilted charge devices would have a total capacitance of 25 pF (50 pF/2). Also, a vertically stacked structure increases the series resistance, which is beneficial when low input impedance tilted charge devices are used.

Referring to FIG. 8, there is shown a simplified cross-section of a device in accordance with another embodiment of the invention and which can be used in practicing another embodiment of a method in accordance with the invention. The semiconductor layer structure of an example of this embodiment is shown in FIG. 9. FIG. 8 illustrates a vertical stack of relatively low impedance tilted charge light-emitting units. Three representative units 81, 82, and 83 are shown. Each such unit comprises, from bottom to top, a coupling region 840, a base region 850 containing a quantum size region 855 and comprising base sub-regions 851 and 852, and an emitter region 860. The emitter region of the top unit (81) of the stack has an emitter terminal 861, and the coupler region of the bottom unit (83) of the stack has a drain terminal 811. In the example of the FIG. 9 layer structure table, the layers of individual light-emitting units (e.g. unit 82 of FIG. 8) are set forth as layers 5-13. The “X10” designation in the “SL” (superlattice) column of the table means that there are ten repetitions (ten light-emitting units) in the stack of this example. Again it will be understood that this number can be varied for a desired application.

In FIG. 8 or 9, if each tilted charge light-emitting diode is, for example, designed for an input impedance of 5 ohms and 50 pF, a vertical stack of ten such tilted charge light-emitting diodes will result in an input impedance of 50 ohms (an industry norm) and a stacked capacitance of only 5 pF. Although the requirements for DC voltage bias is increased from typically 1.2 volts to 12 volts, the required RF modulation voltages would remain essentially the same.

1. A method for producing light emission, comprising the steps of:
providing a layered semiconductor structure that includes a collector region, a first base region, a first emitter region, a coupling region, a second base region, and a second emitter region;
providing a quantum size region within said second base region; and
applying electrical signals with respect to said second emitter region, said first base region and said collector region, to produce light emission from said second base region.

2. The method as defined by claim 1 wherein electrical current applied to said first base region is operative to control light emission from said second base region.

3. The method as defined by claim 1, wherein said step of providing a coupling region comprises providing an electrical drain/coupler selected from the group consisting of a zener diode, a backward diode, a resonant tunneling diode, and an esaki diode.

4. The method as defined by claim 1, wherein said first and second emitter regions and said collector region are provided as semiconductor material of a first conductivity type, and wherein said first and second base regions are provided as semiconductor material of a second conductivity type.

5. The method as defined by claim 4, wherein said first conductivity type is provided as n-type and said second conductivity type is provided as p-type.

6. The method as defined by claim 1, further comprising providing an electrical output port of said semiconductor structure taken with respect to said collector region and said first emitter region.

7. The method as defined by claim 1, wherein said step of providing said layered semiconductor structure comprises depositing arsenic based III-V semiconductor materials for said collector region, said first base region, said first emitter region, said coupling region, said second base region, and said second emitter region.

8. The method as defined by claim 1, wherein said step of providing said layered semiconductor structure comprises depositing arsenic based III-V semiconductor materials for said collector region, said first base region, said coupling region, and said second base region, and depositing lattice matched phosphide based layers for at least one of said first and second emitter regions.

9. The method as defined by claim 1, further comprising providing a quantum size region in said first base region such that said collector region, said first base region, and said first emitter region operates as a further light-emitter in response to said application of electrical signals with respect to said second emitter region, said first base region, and said collector region.

10. The method as defined by claim 8, further comprising providing a quantum size region in said first base region such that said collector region, said first base region, and said first emitter region operates as a further light-emitter in response to said application of electrical signals with respect to said second emitter region, said first base region, and said collector region.

11. A method for producing light emission, comprising the steps of:
providing a layered heterojunction bipolar transistor structure that includes a collector region, a first base region disposed on said collector region, and a first emitter region disposed on said first base region;
disposing, over the first emitter region of said transistor structure, in stacked arrangement, a plurality of layered semiconductor tilted charge light-emitting units, each unit comprising, bottom to top, a coupling region, a second base region containing a quantum size region, and a second emitter region; and
applying electrical signals with respect to the second emitter region of the top unit of the stack, said first base region, and said collector region to produce light emission from the second base region of each of said units.

12. The method as defined by claim 11 wherein electrical current applied to said first base region is operative to control light emission from the second base regions of said units.

13. The method as defined by claim 11, wherein said step of providing said coupling regions of said units comprises providing an electrical drain/coupler for each of said units selected from the group consisting of a zener diode, a backward diode, a resonant tunneling diode, and an esaki diode.

14. The method as defined by claim 11, wherein each of said first and second emitter regions and said collector region are provided as semiconductor material of a first conductivity type, and wherein each of said first and second base regions are provided as semiconductor material of a second conductivity type.

15. The method as defined by claim 14, wherein said first conductivity type is provided as n-type and said second conductivity type is provided as p-type.

16. The method as defined by claim 11, wherein said step of providing said layered semiconductor structure comprises depositing arsenic based III-V semiconductor materials for said collector region, said first base region, said first emitter region, each of said coupling regions, each of said second base regions, and each of said second emitter regions.

17. The method as defined by claim 11, wherein said step of disposing, over the first emitter region of said transistor structure, in stacked arrangement, a plurality of layered semiconductor tilted charge light-emitting units, comprises disposing over the first emitter region of said transistor structure, in stacked arrangement, several such layered semiconductor tilted charge light-emitting units.

18. A method for producing light emission, comprising the steps of:
providing a semiconductor substrate;
disposing, on said substrate, in stacked arrangement, a plurality of layered semiconductor tilted charge light-emitting units, each unit comprising, bottom to top, a coupling region, a base region containing a quantum size region, and an emitter region; and
applying electrical signals with respect to the emitter region of the top unit of the stack and the coupling region of the bottom unit of the stack to produce light emission from the base region of each of said units.

19. The method as defined by claim 18, wherein each of said emitter regions are provided as semiconductor material of a first conductivity type, and wherein each of said base regions are provided as semiconductor material of a second conductivity type.

20. The method as defined by claim 18, wherein the coupling region of each unit is provided as a drain/coupler selected from the group consisting of a zener diode, a backward diode, a resonant tunneling diode, and an esaki diode.

21. The method as defined by claim 18, wherein said step of disposing, on said substrate, in stacked arrangement, a plurality of layered semiconductor tilted charge light-emitting units, comprises disposing on said substrate in stacked arrangement, a multiplicity of such layered semiconductor tilted charge light-emitting units.

22. A light-emitting device, comprising:
a layered semiconductor structure that includes a collector region, a first base region, a first emitter region, a coupling region, a second base region, and a second emitter region; and
a quantum size region within said second base region;
whereby application of electrical signals with respect to said second emitter region, said first base region and said collector region is operative to produce light emission from said second base region.

23. The device as defined by claim 22, wherein said coupling region comprises an electrical drain/coupler selected from the group consisting of a zener diode, a backward diode, a resonant tunneling diode, and an esaki diode.

24. The device as defined by claim 20, wherein said first and second emitter regions and said collector region comprise semiconductor material of a first conductivity type, and wherein said first and second base regions comprise semiconductor material of a second conductivity type.

25. The device as defined by claim 20, wherein said semiconductor materials for said collector region, said first base region, said first emitter region, said coupling region, said second base region, and said second emitter region all comprise arsenic based III-V semiconductor materials.

26. The device as defined by claim 20, further comprising a quantum size region in said first base region such that said collector region, said first base region, and said first emitter region is operative as a further light-emitter in response to said application of electrical signals with respect to said second emitter region, said first base region, and said collector region.

27. A light-emitting device, comprising:
a layered heterojunction bipolar transistor structure that includes a collector region, a first base region disposed on said collector region, and a first emitter region disposed on said first base region; and
a plurality of layered semiconductor tilted charge light-emitting units, disposed over the first emitter region of said transistor structure in stacked arrangement, each unit comprising, bottom to top, a coupling region, a second base region containing a quantum size region, and a second emitter region;
whereby application of electrical signals with respect to the second emitter region of the top unit of the stack, said first base region, and said collector region is operative to produce light emission from the second base region of each of said units.

28. The device as defined by claim 27, wherein said coupling regions of said units comprise an electrical drain/coupler selected from the group consisting of a zener diode, a backward diode, a resonant tunneling diode, and an esaki diode.

29. The device as defined by claim 27, wherein each of said first and second emitter regions and said collector region comprise semiconductor material of a first conductivity type, and wherein each of said first and second base regions are provided as semiconductor material of a second conductivity type.

30. A light-emitting device, comprising:
a semiconductor substrate; and
a plurality of layered semiconductor tilted charge light-emitting units, disposed on said substrate, in stacked arrangement, each unit comprising, bottom to top, a coupling region, a base region containing a quantum size region, and an emitter region;
whereby application of electrical signals with respect to the emitter region of the top unit of the stack and the coupling region of the bottom unit of the stack is operative to produce light emission from the base region of each of said units.

31. The device as defined by claim 30, wherein each of said emitter regions comprise semiconductor material of a first conductivity type, and wherein each of said base regions comprise semiconductor material of a second conductivity type.

32. The device as defined by claim 31, wherein the coupling region of each unit comprises a drain/coupler selected from the group consisting of a zener diode, a backward diode, a resonant tunneling diode, and an esaki diode.
